(19) United States
(12) Patent Application Publication
(10) Pub. No.: US 2014/0016280 A1
(43) Pub. Date: Jan. 16, 2014

(54) SERIALLY ARRANGED PRINTED CIRCUIT BOARD

(71) Applicant: SAMSUNG Electronics Co., Ltd., Suwon-si (KR)

(72) Inventors: Young-Hoon KIM, Cheonan-si (KR); Jong-Wook JEONG, Hwaseong-si (KR); Jeongsam LEE, Cheonan-si (KR); Hyunseok CHOI, Asan-si (KR)

(73) Assignee: SAMSUNG Electronics Co., Ltd.

(21) Appl. No.: 13/940,428

(22) Filed: Jul. 12, 2013

(30) Foreign Application Priority Data
Jul. 12, 2012 (KR) 10-2012-0076196

(51) Int. Cl. H05K 1/18

(52) U.S. Cl. CPC H05K 1/18
USPC 361/748; 174/261; 174/250

(57) ABSTRACT

The present general inventive concept provides a serially arranged printed circuit board including a printed circuit board body and a connector connected to the printed circuit board body configured to exchange a signal with an external device. The printed circuit board body includes a plurality of semiconductor device areas, on which a plurality of semiconductor devices is formed, and a dummy area including a plurality of conductive patterns electrically connecting the connector with the plurality of semiconductor device areas, respectively. Each of the plurality of conductive patterns is formed in two or more multiple layers.

### CROSS-REFERENCE TO RELATED APPLICATIONS

This U.S. non-provisional patent application claims priority under 35 U.S.C. §119 of Korean Patent Application No. 10-2012-0076196, filed on Jul. 12, 2012, the entire contents of which are hereby incorporated by reference.

### BACKGROUND OF THE INVENTION

1. Field of the Invention

The present general inventive concept herein relates to semiconductor devices, and more particularly, to a serially arranged printed circuit board.

2. Description of the Related Art

A serially arranged printed circuit board indicates a printed circuit board on which a plurality of semiconductor devices is formed. A plurality of semiconductor devices formed on one serially arranged printed circuit board is tested at the same time. If the test is completed, the serially arranged printed circuit board is cut, and then a plurality of semiconductor devices is manufactured.

If a serially arranged printed circuit board is used, the number of semiconductor devices being produced in a printed circuit board of the same area increases. Thus, the productivity of semiconductor device increases and the production cost of semiconductor device decreases. If a serially arranged printed circuit board is used, a plurality of semiconductor devices is tested at the same time. Thus, test time of semiconductor devices is reduced and the productivity of the semiconductor devices is improved.

A serially arranged printed circuit board includes a connector which is supplied with various signals. Semiconductor devices formed on a serially arranged printed circuit board are tested according to a signal supplied from the connector. If the number of the semiconductor devices formed on a serially arranged printed circuit board increases, a distance between the connector and a semiconductor device farthest from the connector increases. If a distance between the connector and a semiconductor device increases, a length of a conductive pattern connecting the connector and the semiconductor device increases. If the length of conductive pattern increases, resistance of conductive pattern increases. If the resistance of conductive pattern increases, a level of power supply being supplied to the semiconductor device is reduced. The reduction of the power supply may cause a test failure.

### SUMMARY OF THE INVENTION

The present general inventive concept provides a serially arranged printed circuit board comprising multiple layer conductive patterns.

Additional features and/or utilities of the present general inventive concept will be set forth in part in the description which follows and, in part, will be obvious from the description, or may be learned by practice of the present general inventive concept

The foregoing and/or other features and utilities of the present general inventive concept are achieved by providing a serially arranged printed circuit board comprising a printed circuit board body; and a connector connected to the printed circuit board body being configured to exchange a signal with an external device. The printed circuit board body includes a plurality of semiconductor device areas on which a plurality of semiconductor devices is respectively formed; and a dummy area including a plurality of conductive patterns electrically connecting the connector to the plurality of semiconductor device areas, respectively. Each of the plurality of conductive patterns is formed in two or more multiple layers.

The dummy area may further include a plurality of insulating layers, wherein the two or more multiple layers are separated from each other by the plurality of insulating layers, and wherein parts of each of the plurality of conductive patterns formed in the two or more multiple layers are electrically connected to one another through plugs.

Each of the plurality of conductive patterns may be a conductive pattern to which a power supply voltage is supplied.

Each of the plurality of conductive patterns is formed so that a voltage drop by each of the conductive patterns is less than a reference value.

The reference value may be determined according to an allowable range of the power supply voltage which a plurality of semiconductor devices formed in the plurality of semiconductor device areas supports.

The foregoing and/or other features and utilities of the present general inventive concept may also be achieved by providing a serially arranged printed circuit board comprising a plurality of insulating layers forming a plurality of electrically isolated layers and comprising a first area and a second area; and a conductive pattern formed in the plurality of electrically isolated layers of the first area. Parts of the conductive pattern formed in the plurality of electrically isolated layers are electrically connected to one another through plugs penetrating the plurality of insulating layers. The conductive pattern extends from one layer among the plurality of electrically isolated layers toward the second area.

The serially arranged printed circuit board may further comprise a second conductive pattern formed in the plurality of electrically isolated layers of the first area and electrically connected to the conductive pattern, wherein parts of the second conductive pattern formed in the plurality of electrically isolated layers of the first area are electrically connected to one another through plugs penetrating the plurality of insulating layers, and wherein the second conductive pattern extends from one layer among the plurality of electrically isolated layers toward the second area.

The conductive pattern and the second conductive pattern may extend toward different parts of the second area respectively.

The second area may comprise a plurality of semiconductor device areas on which a plurality of semiconductor devices is formed, and wherein the conductive pattern and the second conductive pattern extend toward different semiconductor device areas of the plurality of semiconductor device areas.

The serially arranged printed circuit board may further comprise a connector configured to be formed on the plurality of insulating layers to be electrically connected to the conductive pattern and receive a signal from outside the serially arranged printed circuit board.

The conductive pattern may be configured to receive a power supply voltage from the connector and supply the received power supply voltage to the second area.

The foregoing and/or other features and utilities of the present general inventive concept are achieved by providing a serially arranged printed circuit board comprising: two or more semiconductor device areas; a connector to receive a signal from outside the serially arranged printed circuit board and respectively supply the received signal to the two or more semiconductor device areas; and two or more conductive patterns respectively connecting the connector with the two or more semiconductor device areas, each of the plurality of conductive patterns being formed in two or more layers of conductive material.

The two or more layers of conductive material may be separated by at least one insulating layer.

Parts of the two or more layers of conductive material may be electrically connected by a plurality of plugs.

The two or more layers of conductive material may be electrically connected to the connector through a conductive component.

The foregoing and/or other features and utilities of the present general inventive concept may also be achieved by providing a serially arranged printed circuit board comprising: a plurality of semiconductor device areas; a connector to receive a signal from outside the serially arranged printed circuit board and respectively supply the received signal to the plurality of semiconductor device areas; and a plurality of conductive patterns, each of the plurality of conductive patterns being formed in a plurality of layers of conductive material to respectively connect the connector with the plurality of semiconductor device areas.

Each of the plurality of layers of conductive material may be separated by at least one insulating layer.

Parts of each of the plurality of layers of conductive material may be electrically connected by a plurality of plugs.

The plurality of layers of conductive material and the plurality of plugs together may form a mesh structure.

The foregoing and/or other features and utilities of the present general inventive concept may also be achieved by providing a method of determining whether a serially arranged printed circuit board is being used, the method comprising: calculating a resistance of a detected side conductor; calculating a length of one of a plurality of conductive patterns; calculating a voltage drop of the one of the plurality of conductive patterns; determining whether the calculated voltage drop exceeds a predetermined reference level; and determining whether the one of the plurality of conductive patterns has a multiple layered structure.

### BRIEF DESCRIPTION OF THE DRAWINGS

These and/or other features and utilities of the present general inventive concept will become apparent and more readily appreciated from the following description of the embodiments, taken in conjunction with the accompanying drawings of which:

FIG. 1 is a perspective view illustrating a serially arranged printed circuit board in accordance with embodiments of the present general inventive concept.

FIG. 2 is a top plan view illustrating a serially arranged printed circuit board in accordance with embodiments of the present general inventive concept.

FIG. 3 is a cross sectional view illustrating a first example of cross section taken along the line III-III′ of FIG. 2.

FIG. 4 is a cross sectional view illustrating a second example of cross section taken along the line III-III′ of FIG. 2.

FIG. 5 is a perspective view illustrating a semiconductor device in accordance with embodiments of the present general inventive concept.

FIG. 6 is a side view illustrating a side of the semiconductor device of FIG. 5.

FIG. 7 is a flow chart illustrating a method of distinguishing whether a serially arranged printed circuit board is used in accordance with embodiments of the present general inventive concept.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept while referring to the figures.

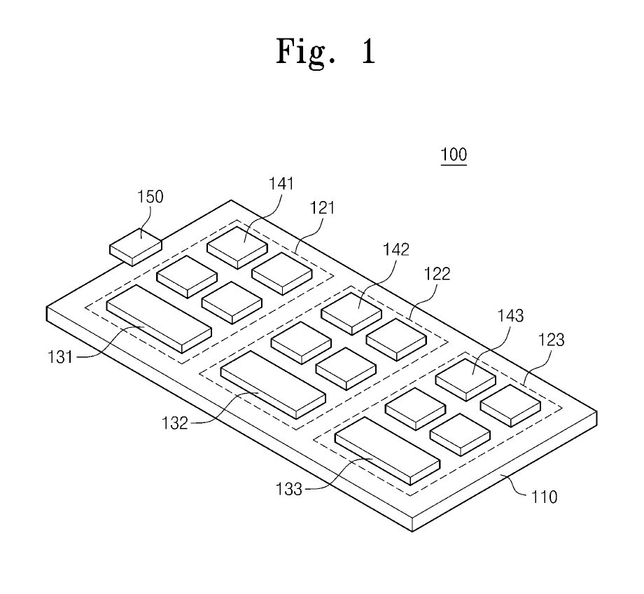

FIG. 1 is a perspective view illustrating a serially arranged printed circuit board 100 in accordance with embodiments of the present general inventive concept. Referring to FIG. 1, the serially arranged printed circuit board 100 includes a printed circuit board body 110, a plurality of semiconductor device areas 121 through 123, first semiconductor packages 131 through 133, second semiconductor packages 141 through 143, and a connector 150.

The semiconductor device areas 121 through 123 are areas in which semiconductor devices are formed. The semiconductor devices formed in the semiconductor device areas 121 through 123 may have the same structure.

The first semiconductor package 131 and the second semiconductor package 141 may be formed in the semiconductor device area 121. The first and second semiconductor packages 131 and 141 may be connected to the printed circuit board body 110 through a ball grid array (BGA) or a pin grid array (PGA).

The first semiconductor package 131 may include a logical package performing a logical operation. The second semiconductor package 141 may include a plurality of memory packages. The first semiconductor package 131 may include a memory controller and the second semiconductor package 141 may include a plurality of nonvolatile memory packages. A semiconductor device formed in the semiconductor device area 121 may be a solid state drive (SSD). However, a semiconductor device formed in the semiconductor device area 121 is not limited to the solid state drive (SSD). A semiconductor device formed in the semiconductor device area 121 may include various types of semiconductor devices manufactured on the basis of a printed circuit board.

A semiconductor device may include an ultra mobile PC (UMPC), a workstation, a netbook, a personal digital assistants (PDA), a portable computer, a web tablet, a tablet computer, a wireless phone, a mobile phone, a smart phone, an e-book, a portable multimedia player (PMP), a portable game machine, a navigation device, a black box, a digital camera, a digital multimedia broadcasting (DMB) player, a three dimensional television, a smart television, a digital audio recorder, a digital audio player, a digital picture recorder, a digital picture player, a digital video recorder, a digital video player, a storage constituting a data center, a device that can transmit and receive information in a wireless environment, one of various electronic devices constituting a home network, one of various electronic devices constituting a computer network, one of various electronic devices constituting a telematics network, and one of various constituent elements constituting a radio-frequency identification (RFID) device or a computing system.

The first semiconductor package 132 and the second semiconductor package 142 may be formed in the semiconductor device area 122. The first semiconductor package 133 and the second semiconductor package 143 may be formed in the semiconductor device area 123. The semiconductor devices formed in the semiconductor device areas 122 and 123 may have the same structure as the semiconductor devices formed in the semiconductor device area 121.

In the printed circuit board body 110, an area that does not belong to the semiconductor device areas 121 through 123 may be a dummy area.

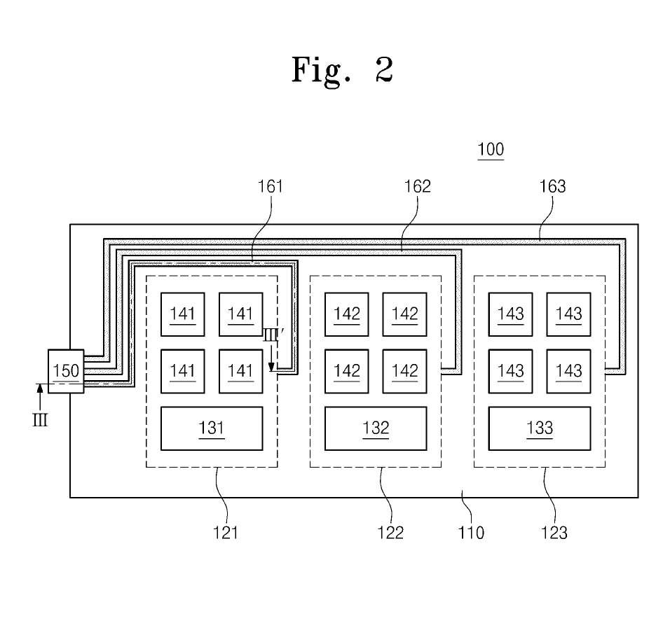

The connector 150 may be connected to the printed circuit board body 110. The connector 150 receives a signal from outside the serially arranged printed circuit board 100 and may supply the received signal to the semiconductor device areas 121 through 123 through conductive patterns (refer to FIG. 2). The connector 150 receives a power supply voltage, a ground voltage, and various signals needed for a test and may respectively supply the received various signals to the semiconductor device areas 121 through 123.

FIG. 2 is a top plan view illustrating a serially arranged printed circuit board 100 in accordance with embodiments of the present general inventive concept. Referring to FIGS. 1 and 2, the serially arranged printed circuit board 100 includes a printed circuit board body 110, a plurality of semiconductor device areas 121 through 123, first semiconductor packages 131 through 133, second semiconductor packages 141 through 143, and a connector 150.

A plurality of conductive patterns 161 through 163 can respectively connect the connector 150 and the semiconductor device areas 121 through 123. The plurality of conductive patterns 161 through 163 may be formed on a surface of the printed circuit board body 110 or inside the printed circuit board body 110. For a brief description, regardless of locations at which the plurality of conductive patterns 161 through 163 are formed, the plurality of conductive patterns 161 through 163 is illustrated in FIG. 2 to assist in describing the present general inventive concept. However, the plurality of conductive patterns is not limited to the locations illustrated in FIG. 2.

The conductive pattern 161 can connect the connector 150 and the semiconductor device area 121. The conductive pattern 162 can connect the connector 150 and the semiconductor device area 122. The conductive pattern 163 can connect the connector 150 and the semiconductor device area 123. The conductive patterns 161 through 163 are supplied with a power supply voltage from the connector 150 and can respectively supply the power supply voltage to semiconductor devices formed on the semiconductor device areas 121 through 123. The conductive patterns 161 through 163 may include copper patterns, silver patterns, or a combination of copper and silver patterns.

The serially arranged printed circuit board 100 supplies a power supply voltage being supplied from the connector 150 to the semiconductor device areas 121 through 123 through the conductive patterns 161 through 163. As a distance between the connector 150 and the semiconductor device areas 121 through 123 increases, a length of the conductive pattern 161, 162 or 163 increases and, consequently, resistance of the conductive pattern 161, 162 or 163 increases. An increase of resistance may cause a voltage drop. For example, a power supply voltage being supplied to the semiconductor device area 123 farthest from the connector 150 may be lower than a range of normal operation voltage of the semiconductor device formed in the semiconductor device area 123.

A conventional serially arranged printed circuit board supplies a power supply to a semiconductor device area through a conductive pattern formed in one layer. Thus, to prevent a voltage drop of the conductive pattern, a size of the conductive pattern has to be increased. If a size of the conductive pattern increases, the number of semiconductor device areas formed in one serially arranged printed circuit board may be reduced. That is, the productivity of the serially arranged printed circuit board and the semiconductor device may be decreased.

To prevent that problem, the conductive patterns 161, 162 and 163 of the serially arranged printed circuit board 100 in accordance with embodiments of the inventive concept are formed in a multiple layer.

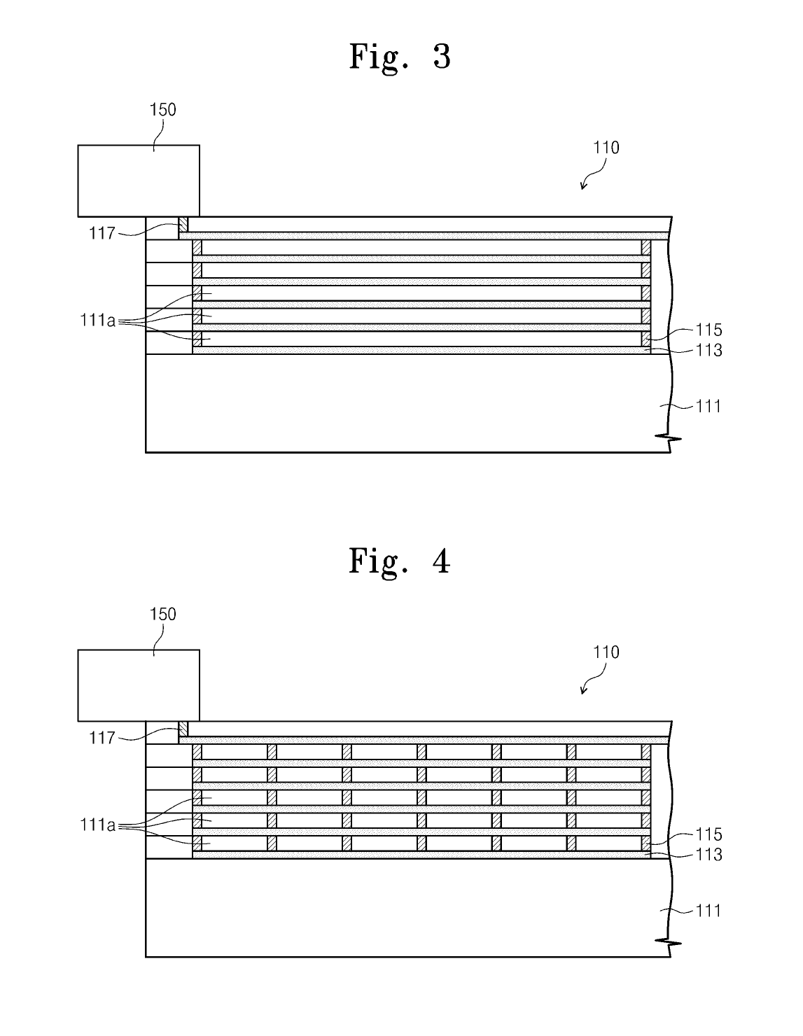

FIG. 3 is a cross sectional view illustrating a first example of the cross section taken along the line III-III′ of FIG. 2. Referring to FIGS. 1 through 3, the printed circuit board body 110 may include a plurality of insulating layers 111. Conductive materials 113 are provided between the insulating layers 111a. The conductive materials 113 are formed on a plurality of layers divided by the plurality of insulating layers 111a. The conductive materials 113 are electrically connected to one another through plugs 115 penetrating the plurality of insulating layers 111a to form the conductive pattern 161. The conductive materials 113 are electrically connected to the connector 150 through a conductive component 117.

One of the conductive materials 113 formed on the plurality of layers extends toward the semiconductor device area 121. The conductive material 113 extending to the semiconductor device area 121 can supply a power supply voltage to the semiconductor device area 121.

If the conductive pattern 161 is formed on the plurality of layers, resistance of the conductive pattern 161 is reduced. If the resistance of the conductive pattern 161 is reduced, a voltage drop caused by the conductive pattern 161 may also be reduced. Thus, an error caused by a power supply voltage, supplied to the semiconductor device areas 121 through 123, becoming lower than a normal operation range of the semiconductor devices during transmission may be prevented.

The conductive pattern 161 may be formed so that a voltage drop caused by the conductive pattern 161 becomes less than a reference value. The reference value may be determined according to an allowable range of power supply voltage supported by a semiconductor device formed in the semiconductor device area 121.

If the conductive pattern 161 is formed on the plurality of layers, resistance of the conductive pattern 161 is reduced without an increase of a size of the conductive material being formed on one layer. Furthermore, if the conductive pattern 161 is formed on the plurality of layers, a size of the conductive material 113 formed on one layer may be reduced. That is, the number of semiconductor device areas 121 through 123 being formed on the printed circuit board 100 may be increased.

FIG. 4 is a cross sectional view illustrating a second example of the cross section taken along the line of FIG. 2. If comparing FIG. 3 with FIG. 4, the number of plugs 115 illustrated in FIG. 4 is greater than the number of plugs illustrated in FIG. 3. That is, the number of plugs 115 connecting the conductive materials 113 being formed on the plurality of layers may be increased. If the number of plugs 115 is increased, the conductive materials 113 can form a mesh structure together with the plugs 115. If the conductive materials 113 and the plugs 115 form a mesh structure, resistance of the conductive pattern 161 may be further reduced.

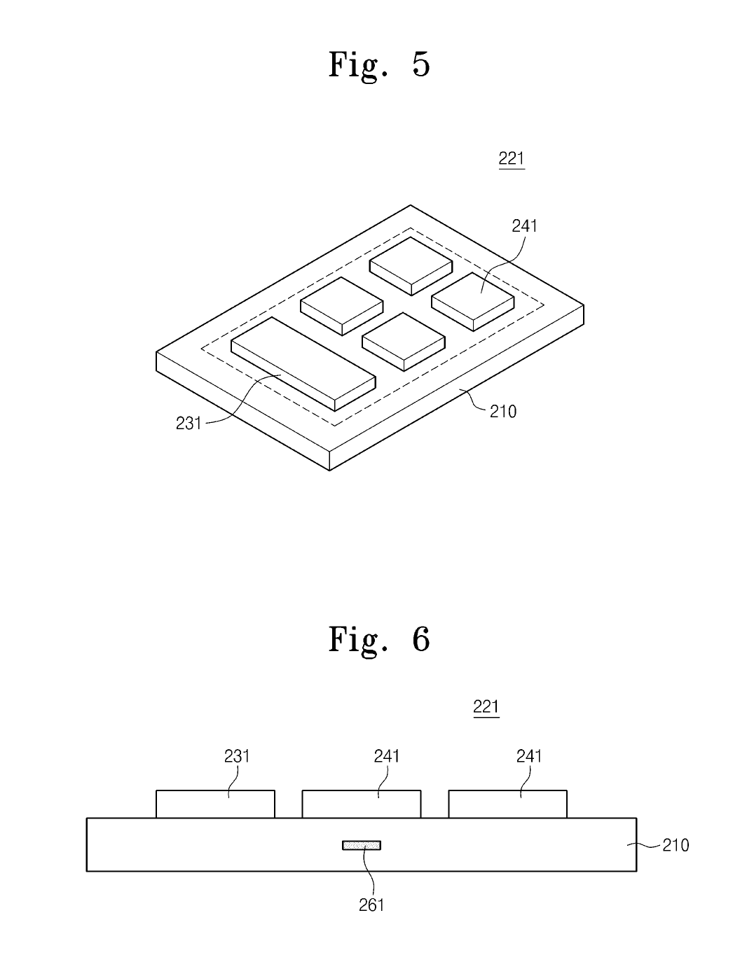

FIG. 5 is a perspective view illustrating a semiconductor device 221 in accordance with embodiments of the present general inventive concept. Referring to FIG. 5, the semiconductor device 221 includes a printed circuit board 210, first semiconductor packages 231, and second semiconductor packages 241.

The semiconductor device 221 may be the first semiconductor device area 121 separated from the serially arranged printed circuit board 100 of FIG. 1. Separating the first semiconductor device area 121 from the serially arranged printed circuit board 100 of FIG. 1 may result in forming the semiconductor device 221.

FIG. 6 is a side view illustrating a side of the semiconductor device 221 of FIG. 5. Referring to FIGS. 5 and 6, a side conductor 261 is formed on a side of the semiconductor device 221. The side conductor 261 may be a result that the conductive pattern 161, described with reference to FIGS. 1 through 4, is cut. If the serially arranged printed circuit board 100 is used, the side conductor 261 may exist on the side of the semiconductor device 221.

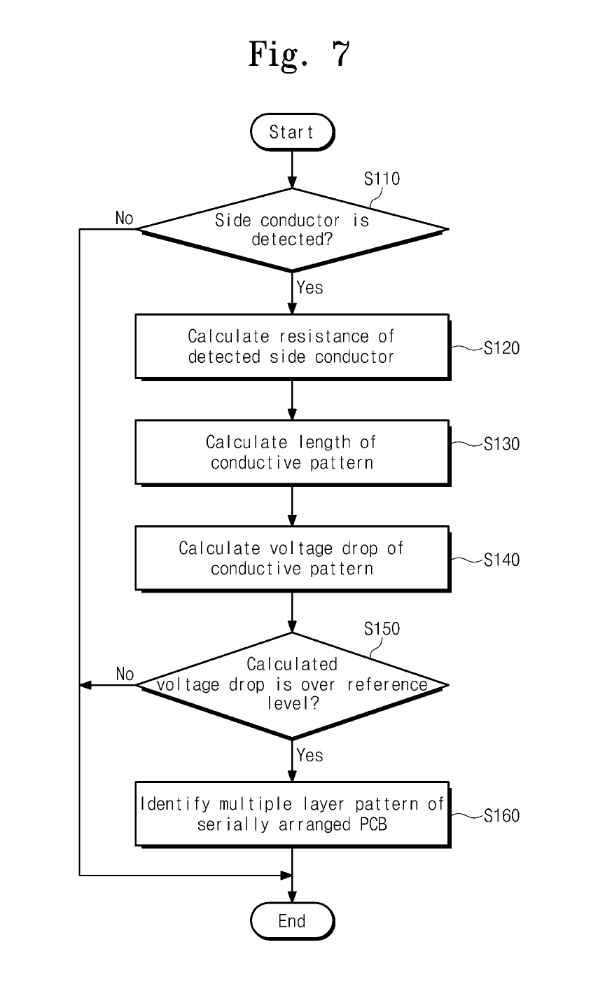

FIG. 7 is a flow chart illustrating a method of distinguishing whether a serially arranged printed circuit board 100 is used in accordance with embodiments of the present general inventive concept. Referring to FIGS. 1, 6, and 7, in a step S110, it is distinguished whether the side conductor 261 is detected. In other words, in step S110 it is distinguished whether the side conductor 261 is detected on the side of the printed circuit board 210 of the semiconductor device 221. If the side conductor 261 is not detected, it is distinguished that the serially arranged printed circuit board 100 is not used. If the side conductor 261 is detected, a step S120 is performed.

In the step S120, resistance of the detected side conductor 261 is calculated. In particular, resistance per unit length of the detected side conductor 261 may be calculated according to an ingredient and a cross sectional area of the detected side conductor 261.

In a step S130, a length of the conductive pattern 161 is calculated. In the serially arranged printed circuit board 100, a length of the conductive pattern 161 connecting the connector 150 and the semiconductor device area 121, on which the semiconductor device 221 is formed, may be calculated. Considering that the semiconductor device 221 corresponds to the semiconductor device area 123 farthest from the connector 150 in the serially arranged printed circuit board 100, a length of the conductive pattern 161 may be calculated. A length of the conductive pattern 161 may be calculated according to a size of the semiconductor device 221, the number of the semiconductor device areas 121 through 123 formed in the one serially arranged printed circuit board 100, and the type of the conductive pattern 161.

In a step S140, a voltage drop of the conductive pattern 161 is calculated. When a power supply voltage of the semiconductor device 221 is applied to one end of the conductive pattern 161, a voltage drop occurring in the other end of the conductive pattern 161 can be calculated. The voltage drop may be calculated according to resistance per unit length of the conductive pattern 161 and a length of the conductive pattern 161.

In a step S150, it is distinguished whether the calculated voltage drop exceeds a reference value. If the calculated voltage drop does not exceed the reference value, it is distinguished that the one serially arranged printed circuit board 100 is not used. If the calculated voltage drop exceeds the reference value, it is distinguished that the one serially arranged printed circuit board 100 is used. Further, if the calculated voltage drop exceeds the reference value, the multiple layer pattern of the serially arranged printed circuit board 100 is identified in step S160. It can be distinguished whether a voltage according to the calculated voltage drop belongs to a range of normal operation voltage of the semiconductor device 221. If the voltage according to the calculated voltage drop is beyond the range of normal operation voltage of the semiconductor device 221, the semiconductor device 221 cannot be normally tested through the serially arranged printed circuit board 100. Even though the semiconductor device 221 cannot be normally tested, if the semiconductor device 221 exists in product form, the conductive pattern 161 is formed in a multiple layer to reduce resistance of the conductive pattern 161 like the serially arranged printed circuit board 100 in accordance with embodiments of the inventive concept.

According to the present general inventive concept, a conductive pattern connecting a connector and a semiconductor device is formed in a plurality of layers. Thus, a voltage drop due to the conductive pattern is prevented and a serially arranged printed circuit board having improved reliability is provided.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

1. A serially arranged printed circuit board comprising:
a printed circuit board body; and
a connector connected to the printed circuit board body being configured to exchange a signal with an external device,
wherein the printed circuit board body comprises:
a plurality of semiconductor device areas on which a plurality of semiconductor devices is respectively formed; and
a dummy area comprising a plurality of conductive patterns electrically connecting the connector to the plurality of semiconductor device areas, respectively,
wherein each of the plurality of conductive patterns is formed in two or more multiple layers.

2. The serially arranged printed circuit board of claim 1, wherein the dummy area further comprises a plurality of insulating layers,
wherein the two or more multiple layers are separated from each other by the plurality of insulating layers, and
wherein parts of each of the plurality of conductive patterns formed in the two or more multiple layers are electrically connected to one another through plugs.

3. The serially arranged printed circuit board of claim 1, wherein each of the plurality of conductive patterns is a conductive pattern to which a power supply voltage is supplied.

4. The serially arranged printed circuit board of claim 1, wherein each of the plurality of conductive patterns is formed so that a voltage drop by each of the conductive patterns is less than a reference value.

5. The serially arranged printed circuit board of claim 4, wherein the reference value is determined according to an allowable range of the power supply voltage which a plurality of semiconductor devices formed in the plurality of semiconductor device areas supports.

6. A serially arranged printed circuit board comprising:
a plurality of insulating layers forming a plurality of electrically isolated layers and comprising a first area and a second area; and
a conductive pattern formed in the plurality of electrically isolated layers of the first area,
wherein parts of the conductive pattern formed in the plurality of electrically isolated layers of the first area are electrically connected to one another through plugs penetrating the plurality of insulating layers, and
wherein the conductive pattern extends from one layer among the plurality of electrically isolated layers toward the second area.

7. The serially arranged printed circuit board of claim 6, further comprising a second conductive pattern formed in the plurality of electrically isolated layers of the first area and electrically connected to the conductive pattern,
wherein parts of the second conductive pattern formed in the plurality of electrically isolated layers of the first area are electrically connected to one another through plugs penetrating the plurality of insulating layers, and
wherein the second conductive pattern extends from one layer among the plurality of electrically isolated layers toward the second area.

8. The serially arranged printed circuit board of claim 7, wherein the conductive pattern and the second conductive pattern extend toward different parts of the second area respectively.

9. The serially arranged printed circuit board of claim 7, wherein the second area comprises a plurality of semiconductor device areas on which a plurality of semiconductor devices is formed, and
wherein the conductive pattern and the second conductive pattern extend toward different semiconductor device areas of the plurality of semiconductor device areas.

10. The serially arranged printed circuit board of claim 6, further comprising a connector configured to be formed on the plurality of insulating layers to be electrically connected to the conductive pattern and receive a signal from outside the serially arranged printed circuit board.

11. The serially arranged printed circuit board of claim 10, wherein the conductive pattern is configured to receive a power supply voltage from the connector and supply the received power supply voltage to the second area.

12. A serially arranged printed circuit board comprising:
two or more semiconductor device areas;
a connector to receive a signal from outside the serially arranged printed circuit board and respectively supply the received signal to the two or more semiconductor device areas; and
two or more conductive patterns respectively connecting the connector with the two or more semiconductor device areas, each of the plurality of conductive patterns being formed in two or more layers of conductive material.

13. The serially arranged printed circuit board of claim 12, wherein the two or more layers of conductive material is separated by at least one insulating layer.

14. The serially arranged printed circuit board of claim 12, wherein parts of the two or more layers of conductive material are electrically connected by a plurality of plugs.

15. The serially arranged printed circuit board of claim 12, wherein the two or more layers of conductive material are electrically connected to the connector through a conductive component.

16-20. (canceled)
